(19) United States
(12) Patent Application Publication
(10) Pub. No.: US 2026/0317895 A1
(43) Pub. Date: Oct. 15, 2026

(54) BLENDED DEPOSITION AND ETCH PROCESS FOR IMPROVED GAPFILL

(71) Applicant: Lam Research Corporation, Fremont, CA (US)

(72) Inventors: David Joseph Mandia, Lake Oswego, OR (US); Matthew Bertram Edward Griffiths, Campbell, CA (US); Sivananda Krishnan Kanakasabapathy, Pleasanton, CA (US)

(21) Appl. No.: 19/473,869

(22) PCT Filed: Apr. 5, 2024
(86) PCT No.: PCT/US2024/023361

§ 371 Date: Oct. 9, 2025

Related U.S. Application Data
(60) Provisional application No. 63/495,237, filed on Apr. 10, 2023.

(51) Int. Cl. C23C 16/04; C23C 16/14; C23C 16/515; C23C 16/52; H01J 37/32; H10P 14/43

(52) U.S. Cl. CPC C23C 16/045; C23C 16/14; C23C 16/515; C23C 16/52; H01J 37/32449; H10P 14/432; H01J 2237/332; H01J 2237/334

(57) ABSTRACT

Provided are methods for performing bottom-up gapfill of features of a substrate using a metal halide precursor and simultaneous introduction of a reducing agent and a halogen-containing etchant into a process chamber at a process temperature below 400° C. The selective gapfill process can be used to fill features with transition metals including molybdenum or tungsten. Some methods involve use of a metal halide precursor and a halogen-containing etchant where both the precursor and the etchant include the same halogen and/or pulsed plasma power.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Deposition of conductive materials an integral part of many semiconductor fabrication processes. These materials may be used for horizontal interconnects, vias between adjacent metal layers, contacts between metal layers and devices, and as lines in memory devices. However, as devices shrink and more complex patterning schemes are utilized in the industry, deposition of thin tungsten films becomes a challenge.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Certain embodiments herein relate to methods and apparatus for filling a feature on a semiconductor substrate. In certain cases, a feature is filled through a composite method including both deposition and etch operations in the same process chamber. The methods enable bottom-up gapfill of features of a substrate by using a metal halide precursor and contemporaneously introducing a reducing agent and a halogen-containing etchant into a process chamber at a process temperature below 400° C. The duration of delivery of halogen-containing etchant may be the same as the duration of delivery of a reducing agent, or for a shorter duration than the duration of the delivery of the reducing agent. The selective gapfill process can be used to fill the features with transition metals including molybdenum or tungsten. Some methods involve use of a metal halide precursor and a halogen-containing etchant where both the precursor and the etchant include the same halogen and/or pulsed plasma power.

Accordingly, in a first aspect, the present disclosure encompasses a method for performing bottom-up gapfill of features of a substrate. In some embodiments, the method includes (a) providing a substrate including a plurality of features, each feature comprising a feature opening and a feature bottom, in a process chamber; (b) introducing a metal halide precursor into the process chamber; (c) introducing a reducing agent into the process chamber; and (d) introducing a halogen-containing etchant into the process chamber; and where a duration of (d) occurs during a duration of (c); and the duration of (d) is the same as or shorter than the duration of (c) such that the metal halide precursor reacts with the reducing agent to deposit a metal film in the feature and the halogen-containing etchant preferentially etches the metal film near the feature opening with respect to the metal film near the feature bottom.

In some embodiments, the bottom-up gapfill is performed by atomic layer deposition, plasma enhanced atomic layer deposition, pulsed chemical vapor deposition or plasma enhanced chemical vapor deposition.

In some embodiments, the metal film is molybdenum or tungsten.

In some embodiments, the reducing agent is hydrogen.

In some embodiments, the halogen-containing etchant and the metal halide precursor comprise the same halogen.

In some embodiments, the metal halide precursor is a molybdenum halide precursor or a tungsten halide precursor.

In some embodiments, the halogen-containing etchant is HCl, Cl₂, MoCl₅, HBr, HF, F₂, MoF₆, or a combination thereof.

In some embodiments, the molybdenum halide precursor is a molybdenum halide, a molybdenum oxyhalide or a combination thereof.

In some embodiments, the molybdenum halide is molybdenum dichloride, molybdenum trichloride, molybdenum tetrachloride, molybdenum pentachloride, molybdenum hexachloride, molybdenum hexafluoride or molybdenum fluoride.

In some embodiments, the molybdenum oxyhalide is molybdenum dichloride dioxide, molybdenum tetrachloride oxide, molybdenum tetrafluoride oxide or molybdenum dibromide dioxide.

In some embodiments, the tungsten halide precursor is tungsten hexafluoride, tungsten pentafluoride, tungsten hexachloride, tungsten pentachloride or a combination thereof.

In some embodiments, a ratio of reducing agent to etchant may be from about 10:1 to about 1:10.

In some embodiments, a concentration of etchant is increased or decreased during (d).

In some embodiments, the duration of (b) is the same as the duration of (c).

In some embodiments, the substrate is not removed from the processing chamber during or between any of operations (a) through (d).

In some embodiments, a temperature of the process chamber is maintained at less than about 400° C.

In some embodiments, the temperature of the process chamber is maintained at about 200° C. to about 300° C., and the process chamber has a pressure of less than about 500 Torr.

In a second aspect, the present disclosure encompasses an apparatus for filling a feature of a semiconductor substrate. In some embodiments, the apparatus includes one or more process chambers; one or more gas inlets into the process chambers and associated flow-control hardware; and a controller having at least one processor and a memory, wherein the processor and the memory are communicatively connected with one another, the at least one processor is at least operatively connected with the associated flow-control hardware, and the memory stores computer-executable instructions for controlling the at least one processor to at least control the associated flow-control hardware to: (a) cause introduction of a metal halide precursor into the process chamber; (b) cause introduction of a reducing agent into the process chamber; and (c) cause introduction of a halogen-containing etchant into the process chamber; and wherein a duration of (c) occurs during the duration of (b); and the duration of (c) is the same as or shorter than the duration of (b).

In some embodiments, the apparatus includes a plasma generator for providing pulsed plasma to the one or more process chambers.

In a third aspect, the present disclosure encompasses a method for performing bottom-up gapfill of features of a substrate. In some embodiments, the method includes (a) providing a substrate including a plurality of features, each feature comprising a feature opening and a feature bottom, in a process chamber; (b) introducing a metal halide precursor into the process chamber; (c) introducing a reducing agent into the process chamber; and (d) introducing a halogen-containing etchant into the process chamber; and wherein a duration of (c) occurs during a duration of (d); and the duration of (c) is the same as or shorter than the duration of (d) whereby the metal halide precursor reacts with the reducing agent to deposit a metal film in the feature and the halogen-containing etchant preferentially etches the metal film near the feature opening with respect to the metal film near the feature bottom.

These and other aspects are described further below with reference to the drawings.

### BRIEF DESCRIPTION OF THE DRAWINGS

FIG. 1 is a flow diagram of a metal deposition method with combined deposition and etch operations in accordance with certain disclosed embodiments.

FIG. 2 is a flow diagram of another metal deposition method with combined deposition and etch operations in accordance with certain disclosed embodiments.

FIG. 3 is a schematic representation of metal deposition methods in a plasma-enhanced atomic layer deposition method with concurrent co-flow of reducing agent and etchant in accordance with certain disclosed embodiments (I) and a conventional metal deposition method (II).

FIG. 4 is a schematic representation of combined deposition and etch operations in a plasma-enhanced atomic layer deposition method with co-flow of an etchant during a portion of introduction of reducing agent with two purge steps (I) or a single purge step (II) per cycle in accordance with certain disclosed embodiments.

FIG. 5A is a schematic representation of combined deposition and etch operations in a pulsed chemical vapor deposition-like method in accordance with certain disclosed embodiments.

FIG. 5B is a schematic representation of combined deposition and etch operations in a plasma-enhanced atomic layer deposition method with co-flow of pulses of a reducing agent during portions of the introduction of an etchant in accordance with certain disclosed embodiments.

FIG. 5C is a schematic representation of combined deposition and etch operations in a plasma-enhanced atomic layer deposition method with co-flow of pulses of etchant during portions of the introduction of reducing agent.

FIG. 6 is a schematic representation of combined deposition and etch operations in a plasma enhanced chemical vapor deposition-like method in accordance with certain disclosed embodiments.

FIG. 7 is a schematic presentation of an apparatus that is suitable for depositing metals in accordance with certain disclosed embodiments.

FIG. 8 shows a schematic view of a multi-station processing system in accordance with certain disclosed embodiments.

FIG. 9 shows a schematic view of a multi-station processing system in accordance with certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Definitions

As used herein, the term “about” is understood to account for minor increases and/or decreases beyond a recited value, which changes do not significantly impact the desired function of the parameter beyond the recited value(s). In some cases, “about” encompasses +/−10% of any recited value. As used herein, this term modifies any recited value, range of values, or endpoints of one or more ranges.

As used herein, the terms “top”, “bottom”, “upper”, “lower”, “above”, and “below” are used to provide a relative relationship between structures. The use of these terms does not indicate or require that a particular structure must be located at a particular location in the apparatus.

As used herein, the phrase “at least one of A, B, and C” should be construed to mean a logical (A or B or C), using a non-exclusive logical “or”, and should not be construed to mean “at least one of A, at least one of B and at least one of C”.

For the purposes of this disclosure, “metal” used in this context should be understood to mean conductor with a maximum resistivity of 500 micro Ohm cm, including metals and conductive metal salts, in particular conductive metal nitrides, e.g., TiN.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction and Context

Chemical vapor deposition (CVD) is a process used to deposit thin films for semiconductor fabrication. CVD typically includes introducing one or more reagents (i.e., precursors) to a substrate in a processing chamber. The reagents react and/or decompose to deposit the films. Plasma enhanced CVD (PECVD) uses plasma in the processing chamber to increase the reaction rates of the reagents and can allow deposition at lower temperatures. Plasma species can also be used to modify the resulting film properties.

ALD is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of precursor from the chamber, (iii) delivery of a second reactant and optionally ignite plasma, and (iv) purging of byproducts from the chamber.

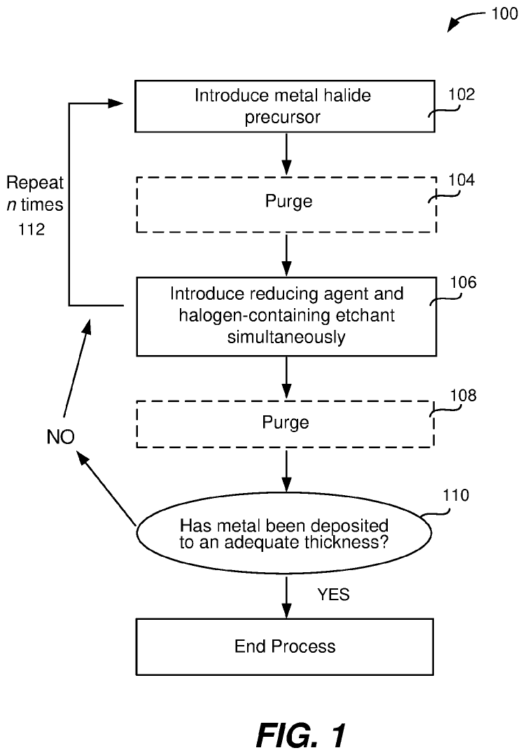

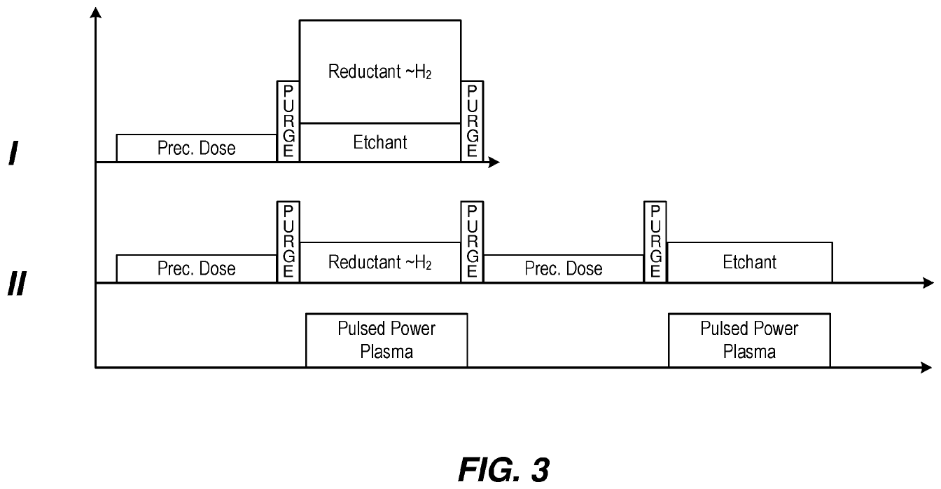

FIG. 1 is a flow chart which depicts method 100 of blended deposition and etch in accordance with certain disclosed embodiments. The method may be described as a blended deposition and etch because the reducing agent and etchant are introduced into the process chamber contemporaneously. In some embodiments, the contemporaneous supply of these two reagents may be fully contemporaneous, when the reducing agent and etchant are flowed into the process chamber for the same length of time as is further explained and illustrated in FIG. 3. As used herein, “simultaneously” or “contemporaneously” mean a time interval or duration of delivery or flow of reagent at the same time. “Fully contemporaneous” refers to a delivery of one reagent for a first duration of time and delivery of another reagent for a second duration of time, where the overlap of the two durations of time is from 95-100%. “Partially contemporaneous” refers to a delivery of one reagent for a first duration of time and delivery of a second reagent for a second duration of time, where the second duration of time is during the first duration of time, but shorter than the first duration of time. In certain embodiments, the method is a low temperature process, in which the process chamber is maintained at a temperature of about 350° C. or less, 300° C. or less, 250° C. or less, 200° C. or less, 150° C. or less or 100° C. or less.

The substrate may be a silicon wafer, e.g., a 200-mm wafer, a 300-mm wafer, or a 450-mm wafer, including wafers having one or more layers of material, such as dielectric, conducting, or semi-conducting material deposited thereon. In various embodiments, the substrate is patterned. A patterned substrate may have “features” such as pillars, poles, trenches, via or contact holes, which may be characterized by one or more of narrow and/or re-entrant openings, constrictions within the feature, and high aspect ratios. One example of a feature is a hole or via in a semiconductor substrate or in a layer on the substrate. Another example is a trench in a substrate or layer. A further example of a feature is a pillar or pole in a semiconductor substrate or a layer on the substrate.

A feature typically has an aspect ratio (depth to lateral dimension). A feature having a high aspect ratio can have a depth to lateral dimension aspect ratio equal to or greater than about 10:1, equal to or greater than about 15:1, equal to or greater than about 20:1, equal to or greater than about 25:1, equal to or greater than about 30:1, equal to or greater than about 40:1, equal to or greater than about 50:1, or equal to or greater than about 100:1.

In various embodiments, the feature may have an under-layer, such as a barrier layer or adhesion layer. Non-limiting examples of under-layers include dielectric layers and conducting layers, e.g., silicon oxides, silicon nitrides, undoped silicon carbides, oxygen-doped silicon carbides, nitrogen-doped silicon carbides, metal oxides, metal nitrides, metal carbides, and metal layers.

The feature(s) may be formed in one or more of the above-described layers.

The methods described herein can be used to fill vertically oriented features formed in a substrate. Such features may be referred to as gaps, recessed features, negative features, unfilled features, or simply features. Filling such features may be referred to as gapfill.

In some embodiments, the feature(s) such as a pillar may have an aspect ratio of at least about 1:1, at least about 2:1, at least about 4:1, at least about 6:1, at least about 10:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm.

A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier.

Features of a substrate can be of various types. In some embodiments, a feature can have straight sidewalls, positively sloped sidewalls, or negatively sloped sidewalls. In some embodiments, a feature can have sidewall topography or sidewall roughness, which may occur as a result of an etch process to form the feature. In some embodiments, a feature can have a feature opening that is greater at the top of the feature than at the bottom, or a feature can have a feature opening that is greater at the bottom of the feature than at the top. In some embodiments, a feature can be partially filled with material or have one or more under-layers. Gapfill of features such as any of foregoing embodiments can depend on feature type and profile.

Because many deposition processes do not have good step coverage properties, i.e., more material is deposited on the field region and near the opening (or “neck” of the feature) than inside the feature, an overhang (or breadloaf-like structure) may be formed. For the purposes of this description, “near the opening” or “near the feature opening” is defined as an approximate position or an area within the feature (i.e., along the side wall of the feature) corresponding to between about 0-10% of the feature depth measured from the field region and may in some embodiments include the upper portion of a feature's sidewalls. In certain embodiments, the area near the opening corresponds to the area at the opening. Further, “inside the feature” is defined as an approximate position or an area within the feature corresponding to between about 20-60% of the feature depth measured from the field region on the top of the feature. For the purposes of this description, “near the bottom” or “near the feature bottom” is defined as an approximate position or an area within the feature (i.e., along the side wall of the feature) corresponding to between about 0-40% of the feature depth measured from the bottom of the feature.

Typically, when values for certain parameters (e.g., thicknesses) are specified “near the opening” or “inside the feature”, these values represent a measurement or an average of multiple measurements taken within these positions/areas. In certain embodiments, an average thickness of the deposited metal near the opening is at least about 10% greater than that inside the feature. In more specific embodiments, this difference may be at least about 25%, at least about 50%, or at least about 100%. In order to perform gapfill without an overhang, the blended deposition and etch method disclosed herein may be utilized.

The deposition method according to the present disclosure can be used to deposit transition metals such as nickel (Ni), cobalt (Co), copper (Cu), molybdenum (Mo), ruthenium (Ru), iridium (Ir), platinum (Pt), palladium (Pd) and tungsten (W). In some embodiments, the deposition method is used for metal gapfill in contact holes and middle of line (MOL) and back end of line (BEOL) trenches/vias. In some embodiments, the liner layer includes titanium/titanium nitride (TiN), tungsten carbonitride (WCN), or tantalum/tantalum nitride (TaN). Alternatively, the deposition process can be used with oxide sidewalls or with any other metal or dielectric barrier materials.

Returning to FIG. 1, operation 102 is an introduction of a metal precursor into the processing chamber which houses a semiconductor substrate. Selection of the precursor depends upon the metal film to be deposited on the substrate. In certain embodiments the metal is tungsten (W) or molybdenum (Mo). The precursor can be introduced in a vaporized form in a flow of inert gas such as argon, helium, or nitrogen (N₂).

Deposition of tungsten may be achieved with a variety of volatile precursors. In some embodiments halogen-containing tungsten precursors, such as WHalₓ, where Hal is a halogen (e.g., F, Cl, Br, and/or I) and x is from 2 to 6, are used. In some embodiments, a tungsten chloride is used. Tungsten chlorides include tungsten pentachloride (WCl₅), tungsten hexachloride (WCl₆), tungsten tetrachloride (WCl₄), tungsten dichloride (WCl₂), and mixtures thereof. In other examples tungsten fluoride, such as tungsten hexafluoride (WF₆) may be used. In some embodiments, the tungsten-containing precursor is tungsten hexacarbonyl (W(CO)₆), WCl₅, WCl₆ or WF₆.

Deposition of molybdenum may be achieved, for example, using molybdenum precursors having from two (MoL₂) to six (MoL₆) ligands where the molybdenum may be in a wide range of oxidation states ranging from 0 to +6. Suitable molybdenum precursors may also be dimolybdenum compounds having 1) two molybdenum atoms singly or multiply bonded to one another; or 2) two molybdenum atoms connected by a linking group such as a bidentate ligand.

In some embodiments, the molybdenum precursors include molybdenum hexacarbonyl (Mo(CO)₆), molybdenum oxyhalide precursors such as molybdenum oxytetrachloride (MoOCl₄) or molybdenum dichloride dioxide (MoO₂Cl₂) and molybdenum halide precursors such as molybdenum chloride ([MoCl₅]₂) or molybdenum hexafluoride (MoF₆).

Other metals such as aluminum, gallium, indium, bismuth, titanium, zirconium, hafnium, vanadium, niobium, tantalum, chromium, technetium, rhenium, rhodium, ruthenium, osmium or platinum may be deposited using the metal precursors AlCl₃, GaCl₃, InCl₃, BiCl₃, BiF₅, TiF₄, TiCl₄, ZrCl₄, HfCl₄, VF₅, VCl₄, NbF₅, NbCl₅, TaF₅, TaCl₅, CrF₅, CrF₅, TcF₆, ReF₆, ReF₇, Re₂Cl₁₀, RhF₅, RhF₆, RuF₅, RuF₆, OsF₆ and PtF₆ respectively.

The metal halide precursor may be flowed for from about 50 ms to about 10000 ms.

Operation 104 is an optional purge step. Purging the chamber may involve flowing a purge gas or a sweep gas, which may be a carrier gas used in other operations or may be a different gas. In some embodiments, purging may involve evacuating the chamber. Examples of purge gases include argon (Ar), nitrogen (N₂), hydrogen (H₂), helium (He), oxygen (O₂), krypton (Kr), xenon (Xe), neon (Ne), and combinations thereof. In various embodiments, the purge gas is an inert gas. The purge gas may include one or more gases. In some embodiments, operation 104 may include one or more evacuation subphases for evacuating the process chamber. Alternatively, it will be appreciated that purges may be omitted in some embodiments. Operation 104 may have any suitable duration, such as between about 0 seconds and about 60 seconds, for example about 0.01 seconds.

In some embodiments, increasing a flow rate of one or more purge gases may decrease the duration of a purge. For example, a purge gas flow rate may be adjusted according to various reactant thermodynamic characteristics and/or geometric characteristics of the process chamber and/or process chamber plumbing for modifying the duration of the purge. In one non-limiting example, the duration of a purge phase may be adjusted by modulating purge gas flow rate. This may reduce deposition cycle time, which may improve substrate throughput.

The purge gas can be flowed to a chamber housing the substrate at a flow rate between about 1000 sccm and about 40000 sccm (e.g., about 100 to 2000 sccm). The purge gas can be flowed for any useful period (e.g., about 0.1 to 10 seconds) and any useful pressure (e.g., about 0.5 to 25 Torr).

In operation 106, at least one etchant and at least one reducing agent are simultaneously introduced into the process chamber. As used herein, “simultaneously” or “contemporaneously” mean a time interval or duration of delivery or flow of reagent at the same time. As shown in operation 106, the etchant delivery and the time interval or duration of the reducing agent delivery are the same. While the etchant and reducing agent are delivered at the same time, they each may be delivered at different flow rates. Furthermore, the concentration of etchant may be either held constant or varied (i.e., increased gradually or tapered off) throughout the duration of its delivery. The ratio of reducing agent to etchant may be tuned in to achieve a desired outcome or property of the deposited metal. Properties include, but are not limited to, deposition rate, uniformity, resistivity, thickness and step coverage of the film in the feature. The tuning can also be used to modulate the full-wafer uniformity of these properties.

In some embodiments, the ratio of reducing agent to etchant is from about 10,000:1 to about 10:1. The flow rates, concentrations and ratios of etchant and flow rate may be the same in every cycle or may be independently adjusted from cycle to cycle.

The reducing agent is typically a reducing gas. Suitable examples of reducing agents include H₂, SiH₄, NH₃, or B₂H₆. In some embodiments, the reducing agent may be in plasma form, such as a hydrogen plasma.

In some embodiments, the reducing agent is hydrogen, ammonia, hydrazine, silane, disilane, trisilane, germane, digermane, diborane or a combination thereof.

Exposing the substrate to the reducing agent may include contacting the substrate with the reducing agent for a time of between about 0.1 seconds and about 180 seconds; between about 0.5 seconds and 60 seconds; or between about 0.1 seconds at 10 seconds. The flow rate of the reducing agent during the exposure of the substrate may be less than 30 slm, or less than 15 slm, or less than 10 slm, or less than 5 slm, or less than 2 slm or even less than 0.1 slm in some embodiments. The flow rate of the reducing agent may range from about 0.1 to 30 slm, from about 5 to 15 slm, or equal to or greater than 10 slm.

By “etchant” is meant any compound used to remove a material such as a layer, byproduct or contaminant from a surface. In some embodiments, the etchant is a halogen-containing etchant such as chlorine (Cl₂), fluorine (F₂), bromine (Br₂), iodine (I₂), hydrogen chloride (HCl), hydrogen fluoride (HF), hydrogen iodide (HI), chlorine trifluoride (ClF₃), trifluoromethane (CHF₃), fluoromethane (CH₃F), octafluorocyclobutane (C₄F₈), hexafluorobutadiene (C₄F₆), hexafluorocyclopentadiene (C₅F₆), carbon tetrafluoride (CF₄), nitrogen trifluoride (NF₃), boron trichloride (BCl₃), boron trifluoride (BF₃), hydrogen iodide (HI), hydrogen bromide (HBr), sulfur tetrafluoride (SF₄), sulfur hexafluoride (SF₆), thionyl chloride (SOCl₂), phosphorus pentafluoride (PF₅) or a combination thereof.

In some embodiments, a single etchant may be sufficiently effective. In some embodiments a combination including more than one etchant may be utilized. Examples of combinations include oxygen (O₂) with one of the above halogen-containing etchants such as chlorine and oxygen; or fluorine and oxygen. Alternatively, carbon dioxide (CO₂) may be combined with one of the above halogen-containing etchants. If a combination of etchants is utilized, they may be flowed through delivery lines together (concomitantly), or sequentially (one following the other). The etchant may be co-flowed with an inert gas, such as argon. In some embodiments, etchants are combined. For example, the halogen-containing etchant may be co-flowed with a non-halogen containing etchant.

In some embodiments, the etchant is MoCl₅, MoF₆ or any of the other metal halides described above.

Flow rates of the etchant typically depend on a size of the chamber, etching rates, etching uniformity, and other parameters. They will typically be much lower than the flow rate of the reducing agent. For example, a flow rate for a 195-liter chamber per station may be between about 25 sccm and 10,000 sccm or, in more specific embodiments, between about 50 sccm and 1,000 sccm. In certain embodiments, the flow rate is less than about 2,000 sccm, less than about 1,000 sccm, or more specifically less than about 500 sccm. It should be noted that these values are presented for one individual station configured for processing a 300-mm wafer substrate. Flow rates can be scaled up or down depending on the substrate size, the number of stations in the apparatus (e.g., quadruple for a four-station apparatus), the processing chamber volume, and other factors.

Etchant may be delivered to the process chamber for a duration of from about 0.1 to about 10 seconds.

In some embodiments, the etchant or etchant combination is halogen-containing, and the halogen of the etchant of operation 106 is the same as the halogen substituents on the metal halide precursor utilized in operation 102. For example, if the metal to be deposited is molybdenum, the chlorine-containing molybdenum precursors including MoO₂Cl₂ or MoCl₅ may be utilized in conjunction with a chlorine-containing etchant such as HCl/Cl₂; or a fluorine-containing molybdenum precursor such as MoF₆ may be utilized in conjunction with a chlorine-containing etchant such as HBr/HF/F₂. If the metal to be deposited is tungsten, the chloride-containing tungsten precursor WCl₅ may be utilized in conjunction with a chloride containing etchants such as HCl/Cl₂; or the fluorine-containing tungsten precursor WF₆ may be utilized in conjunction with a fluorine-containing etchant such as HBr/HF/F₂.

Without wishing to be bound by theory, the selection of a common halogen for both etchant and precursor may serve to enhance etching at the top surface and upper sidewalls of a feature; overcoming any formation of overhangs of a breadloaf-like structure near the opening of the feature. A breadloaf or breadloaf-like structure may also be referred to as a bottleneck. Furthermore, selection of a reducing agent such as hydrogen in conjunction with the use of halogen-containing etchants may be advantageous since the reactive species of the halogen-containing etchants may be relatively heavier in terms of atomic weight than the reactive species of the hydrogen, inducing the reactive species of the halogen-containing etchants to remain near the opening of the feature and etch preferentially therein. When such combinations are utilized, a top heavy etch (i.e.-an etchant which etches more near the opening than at the bottom of the feature) as blended with deposition can result in a super-conformal deposition of metal; thus improving gapfill.

Operation 108 is a second optional purge step. In process 100, either purge 104 or 108 may be included; both purge 104 and 108 may be included; or no purge may be utilized.

In operation 110, a determination of whether or not the metal deposited is of a desired thickness. As used herein, “metal” refers to a film only including metal or a film which contains a metal with additional components. Metal can be deposited for a variety of semiconductor applications. Therefore, the desired thickness will depend upon the particular application. In some embodiments metal may be deposited as a conformal layer to a thickness of between about 0.1-10 nm on a substrate.

If a thicker film is desired, operation 112 is a process flow path indicating that after operation 106, operation 102 can commence again, repeating n times. In process flow path 112, n is the number of cycles which may be from 1 to 50 or from 20 to 40. The cycle of operations 102 and 106 with optional purge 104 can be repeated as many times as necessary. As used herein, the term “cycle” refers to a particular set of sequential operations.

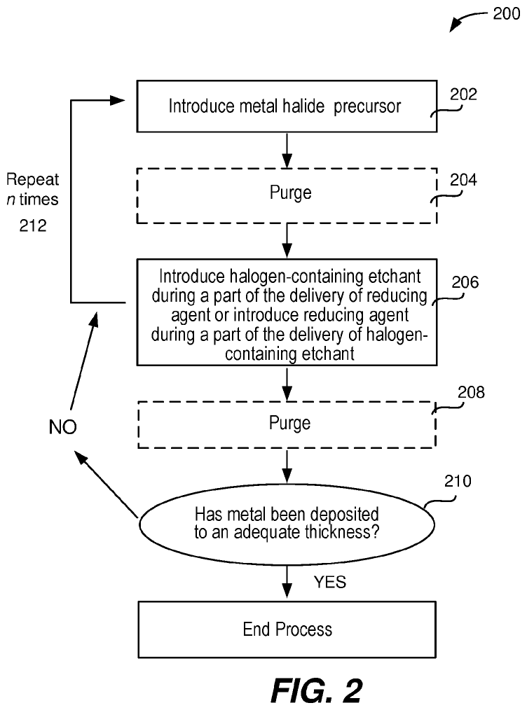

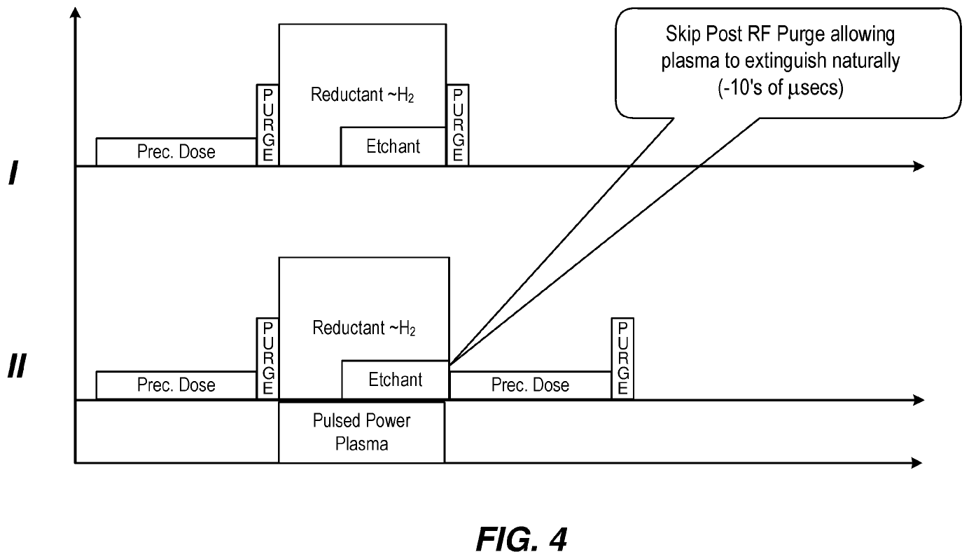

FIG. 2 is a flow chart which depicts another method 200 of blended deposition and etch in accordance with certain disclosed embodiments. Method 200 illustrates a contemporaneous supply of reducing agent and etchant which is partially contemporaneous, when the etchant is flowed into the process chamber during reducing agent delivery but reducing agent delivery may continue after the etchant introduction into the processing chamber or begin before etchant flow into the processing chamber. These conditions are illustrated in FIGS. 4, 5A, 5C and 6 and discussed further below.

Returning to FIG. 2, operation 202 is the introduction of a metal precursor into the process chamber and is similar to the previously described operation 102.

Operations 204 and 208 are optional purges, similar to the previously described purges of operations 104 and 108.

Operation 206 is an introduction of reducing agent and etchant into the process chamber. The etchant is introduced during the introduction of reducing agent. However, the reducing agent may additionally be flowed into the process chamber either before, after, or before and after etchant is introduced. The flow of reducing agent is thus partially contemporaneous with the flow of the etchant. Alternatively, the reducing agent may be introduced in pulses during etchant delivery.

Operation 210 is a determination similar to operation 110 as described above. Operation 212 is a flow path similar to flow path 112, indicating that operations 206 and 202 can be repeated as many times as necessary until a desired thickness of metal is obtained.

FIG. 3 is a schematic representation of a thermal or plasma enhanced atomic layer deposition with concurrent co-flow of reducing agent and etchant in accordance with certain disclosed embodiments (I) as compared to a conventional sequential metal deposition method (II). As shown in the illustration for conventional process (II) the precursor, reducing agent and etchant are dosed sequentially, interspersed with purges. However, in the disclosed blended deposition and etch method, reducing agent and etchant are concurrently introduced instead of being introduced sequentially. In this embodiment, the duration of the flow of etchant into the process chamber is the same as the duration of the flow of reducing agent into the process chamber.

As shown in FIG. 3, a pulsed power plasma may be utilized during the co-flow delivery of reducing agent and etchant. As used herein, “pulsed power plasma” refers to a method in which a plasma source is turned on, igniting a plasma, and then the power of the source is varied in a pulsed manner between two or more values. Within a single duty cycle, the plasma source power may vary in a step function i.e., between discrete integer values of power or in an incremental “linear” fashion. The power may also be varied in a cyclical fashion i.e. from 500 W (watts) to 0 W to 500 W to 0 W etc. or in an incrementally changing fashion i.e. from 0 W to 100 W to 200 W to 300 W to 400 W to 500 W or 100 W to 300 W to 500 W to 1000 W etc. where the incremental change is not consistent, or in a combination of the two i.e. from 100 W to 300 W to 500 W to 0 W to 500 W to 300 W to 100 W. Other permutations of plasma power setpoint variation which may not be listed here specifically are still considered to be consistent with “pulsed power plasma”. The power setpoint can be any number between 0 W, 50 W and 3000 W.

Pulsed plasma methods and systems are described for example in U.S. Pat. No. 10,566,211, issued Feb. 18, 2020 and entitled “CONTINUOUS AND PULSED RF PLASMA FOR ETCHING METALS”, the disclosure of which is incorporated by reference herein.

In some embodiments, the range of power may be from about 50 W to about 3,000 W. In some embodiments, the frequency of the plasma pulses is from about 1Hz to about 400 kHz. In some embodiments, the range of duty cycles is from about 1% to about 99%.

FIG. 4 is a schematic representation of combined deposition and etch operations in a plasma-enhanced atomic layer deposition method with co-flow of an etchant during a portion of introduction of reducing agent with two purge steps (I) or a single purge step (II, also referred to as a no plasma purge PE ALD) per cycle in accordance with certain disclosed embodiments. Skipping the post plasma pulse purge allows the plasma to extinguish naturally.

Process I and process II differ only in terms of the purge steps. For either process I or process II, etchant and reducing agent are co-flowed, but introduction of the reducing agent begins before the concurrent co-flow of reducing agent and etchant.

As shown in FIG. 4, a pulsed power plasma (as described above) may be utilized during the co-flow delivery of reducing agent and etchant.

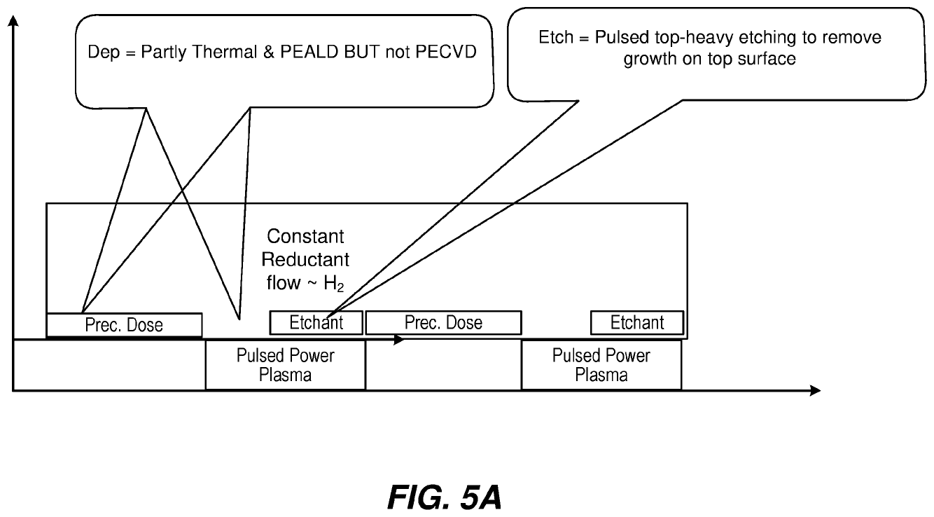

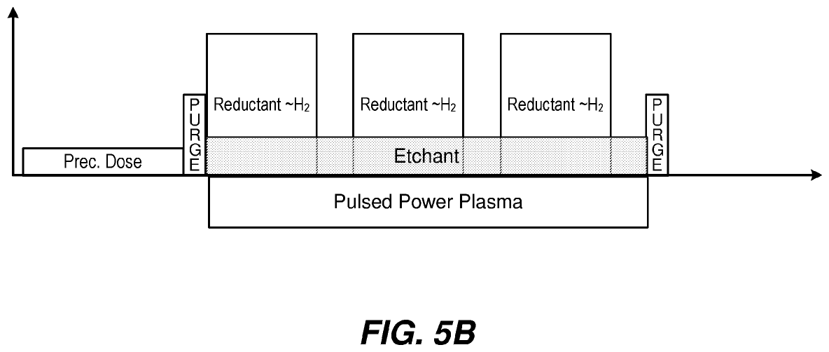

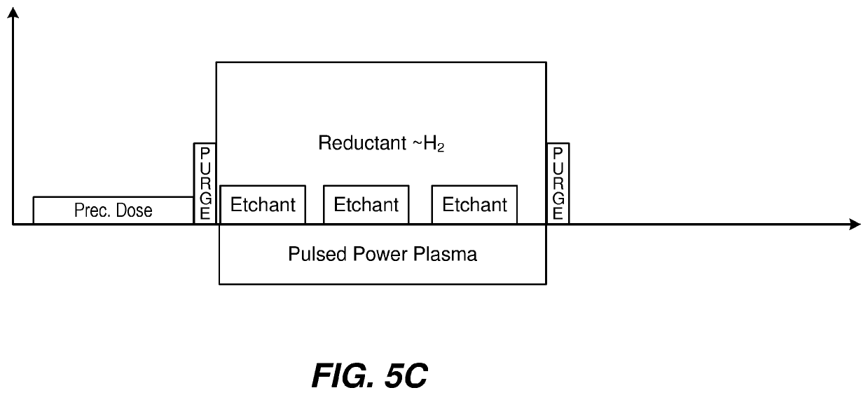

FIG. 5A is a schematic representation of combined deposition and etch operations in a pulsed chemical vapor deposition-like method in accordance with certain disclosed embodiments. This embodiment may be referred to as a no plasma purge PE ALD method. In this embodiment, the etchant is also co-flowed with the reducing agent for the blended method. However, the etchant and reducing agent flows are only partially contemporaneous since the reducing agent flow is continuous but the etchant flow is turned on and off in pulses.

In addition, as shown in FIG. 5A, a pulsed power plasma (as described above) may be on during flow of reducing agent and during the co-flow delivery of reducing agent and etchant.

FIG. 5B is a schematic representation of combined deposition and etch operations in a plasma-enhanced atomic layer deposition method with co-flow of pulses of a reducing agent during portions of the introduction of an etchant in accordance with certain disclosed embodiments. As illustrated, multiple pulses of reducing agent may be delivered to the process chamber during continuous delivery of an etchant. For example, instead of one three second long pulse of reducing agent, three one second pulses of reducing agent may be delivered to the process chamber in certain embodiments.

In addition, as shown in FIG. 5B, a pulsed power plasma (as described above) may be on for the duration of etchant delivery to a process chamber; which also coincides with the periodic delivery of pulses of reducing agent.

FIG. 5C is a schematic representation of combined deposition and etch operations in a plasma-enhanced atomic layer deposition method with co-flow of pulses of etchant during portions of the introduction of reducing agent. As illustrated, multiple pulses of an etchant may be delivered to the process chamber during continuous delivery of a reducing agent. For example, instead of one three second long pulse of etchant, three one second pulses of etchant may be delivered to the process chamber in certain embodiments.

In addition, as shown in FIG. 5C, a pulsed power plasma (as described above) may be on for the duration of reducing agent delivery to a process chamber; which also coincides with the periodic delivery of pulses of etchant.

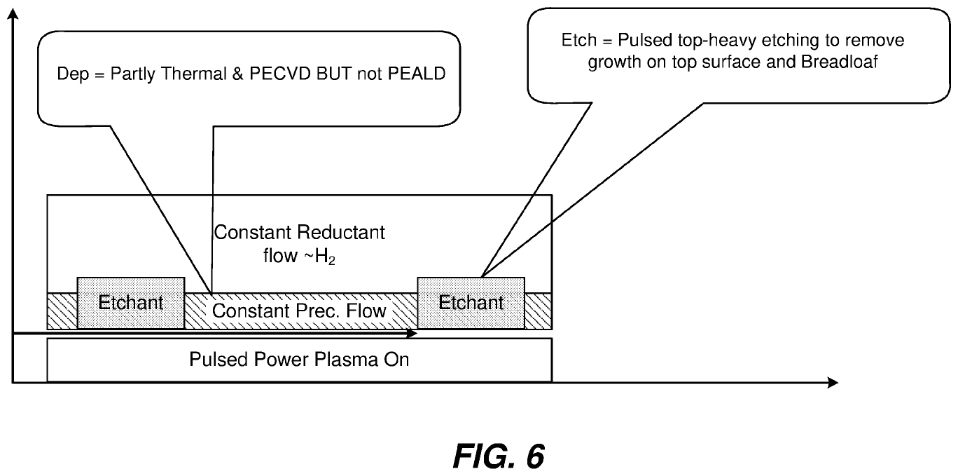

FIG. 6 is a schematic representation of combined deposition and etch operations in a plasma enhanced chemical vapor deposition-like method in accordance with certain disclosed embodiments. In this embodiment of the disclosed blended method, both the precursor flow and reducing agent flow are continuous, but the etchant flow is turned on and off in pulses. In this manner, the etchant and reducing agent are co-flowed in a partially contemporaneous manner.

In addition, as shown in FIG. 6, a pulsed power plasma (as described above) may be on for the duration of reducing agent and precursor delivery to a process chamber; which also coincides with the periodic delivery of pulses of etchant.

The foregoing description is merely illustrative in nature and is in no way intended to limit the disclosure, its application or uses. The broad teaching of the disclosure can be implemented in a variety of forms. Therefore, while this disclosure includes particular examples, the true scope of the disclosure should not be so limited since other modifications will become apparent upon a study of the drawings, the specification and the following claims. It should be understood that one or more steps within a method may be executed in a different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

### Apparatus

The deposition methods described herein can be carried out in a variety of apparatuses. A suitable apparatus includes a processing chamber having one or more inlets for introduction of reactants, a substrate holder in the process chamber configured to hold the substrate in place during deposition, and, optionally, a plasma generating mechanism configured for generating a plasma in a process gas. The apparatus may include a controller having program instructions for causing any of the method steps described herein. The deposition methods described herein may be carried out in corresponding ALD and CVD apparatuses.

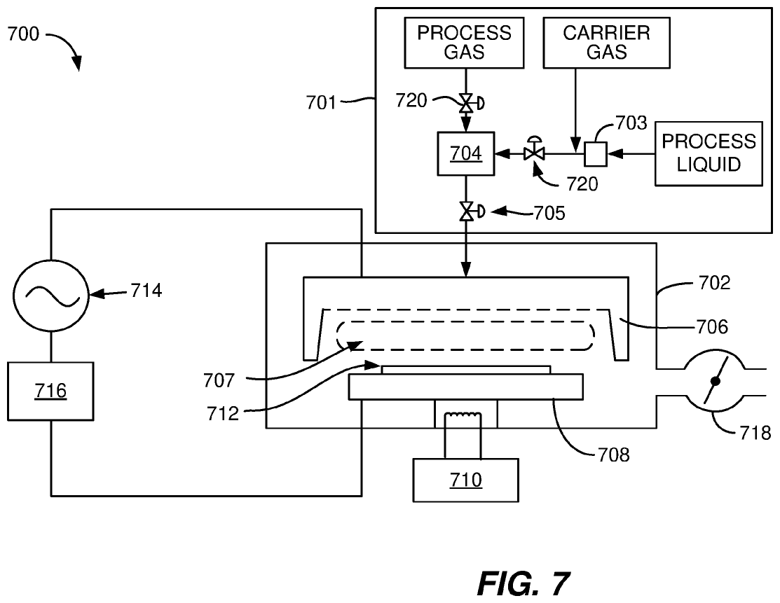

An example of a deposition apparatus suitable for depositing metal using provided methods is shown in FIG. 7 which schematically illustrates an embodiment of a process station 700 that may be used to deposit material using atomic layer deposition (ALD) and/or chemical vapor deposition (CVD), either of which may be plasma enhanced. For simplicity, the process station 700 is depicted as a standalone process station having a process chamber body 702 for maintaining a low-pressure environment. However, it will be appreciated that a plurality of process stations 700 may be included in a common process tool environment. Further, it will be appreciated that, in some embodiments, one or more hardware parameters of process station 700, including those discussed in detail below, may be adjusted programmatically by one or more computer controllers.

Process station 700 fluidly communicates with reactant delivery system 701 for delivering process gases to a distribution showerhead 706. Reactant delivery system 701 includes a mixing vessel 704 for blending and/or conditioning process gases for delivery to showerhead 706. One or more mixing vessel inlet valves 720 may control introduction of process gases to mixing vessel 704. Similarly, a showerhead inlet valve 705 may control introduction of process gasses to the showerhead 706.

Some molybdenum-containing precursors may be stored in solid or liquid form prior to vaporization and subsequent delivery to the process station. For example, the embodiment of FIG. 7 includes a vaporization point 703 for vaporizing solid reactant to be supplied to mixing vessel 704. In some embodiments, vaporization point 703 may be a heated vaporizer. In some embodiments a flow of an inert gas is passed over the heated solid molybdenum precursor, or bubbled through the heated liquid molybdenum precursor, under sub-atmospheric pressure, and carries the precursor vapor to the process chamber. The precursor vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 703 may be heat traced. In some examples, mixing vessel 704 may also be heat traced. In one non-limiting example, piping downstream of vaporization point 703 has an increasing temperature profile extending from approximately 100° C. to approximately 200° C. at mixing vessel 704.

Showerhead 706 distributes process gases toward substrate 712. In the embodiment shown in FIG. 7, substrate 712 is located beneath showerhead 706, and is shown resting on a pedestal 708. It will be appreciated that showerhead 706 may have any suitable shape and may have any suitable number and arrangement of ports for distributing processes gases to substrate 712. While not explicitly shown, in some embodiments the showerhead 706 is a dual plenum showerhead that includes at least two types of conduits, where the first type of conduit is dedicated to delivery of molybdenum-containing precursor vapor, and the second type of conduit is dedicated to delivery of the second (or other) reactant. In these embodiments the molybdenum-containing precursor and the reactant are not allowed to mix in the conduits prior to entry to the process chamber, and do not share the conduits if delivered to the chamber consecutively.

In some embodiments, a microvolume 707 is located beneath showerhead 706. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 708 may be raised or lowered to expose substrate 712 to microvolume 707 and/or to vary a volume of microvolume 707. For example, in a substrate transfer phase, pedestal 708 may be lowered to allow substrate 712 to be loaded onto pedestal 708. During a deposition process phase, pedestal 708 may be raised to position substrate 712 within microvolume 707. In some embodiments, microvolume 707 may completely enclose substrate 712 as well as a portion of pedestal 708 to create a region of high flow impedance during a deposition process.

Optionally, pedestal 708 may be lowered and/or raised during portions the deposition process to modulate process pressure, reactant concentration, etc., within microvolume 707. In one scenario where process chamber body 702 remains at a base pressure during the deposition process, lowering pedestal 708 may allow microvolume 707 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

While the example microvolume variations described herein refer to a height-adjustable pedestal, it will be appreciated that, in some embodiments, a position of showerhead 706 may be adjusted relative to pedestal 708 to vary a volume of microvolume 707. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712. It will be appreciated that, in some embodiments, one or more of these example adjustments may be performed programmatically by one or more suitable computer controllers.

Returning to the embodiment shown in FIG. 7, showerhead 706 and pedestal 708 electrically communicate with RF power supply 714 and matching network 716 for powering a plasma. In other embodiments apparatuses without a plasma generator are used for depositing molybdenum-containing films using provided methods. In some embodiments, the plasma energy may be controlled by controlling one or more of a process station pressure, a gas concentration, a radio frequency (RF) source power, an RF source frequency, and a plasma power pulse timing. For example, RF power supply 714 and matching network 716 may be operated at any suitable power to form a plasma having a desired composition of radical species. Likewise, RF power supply 714 may provide RF power of any suitable frequency. In some embodiments, RF power supply 714 may be configured to control high-and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 708 may be temperature controlled via heater 710. Further, in some embodiments, pressure control for deposition process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to process station 700.

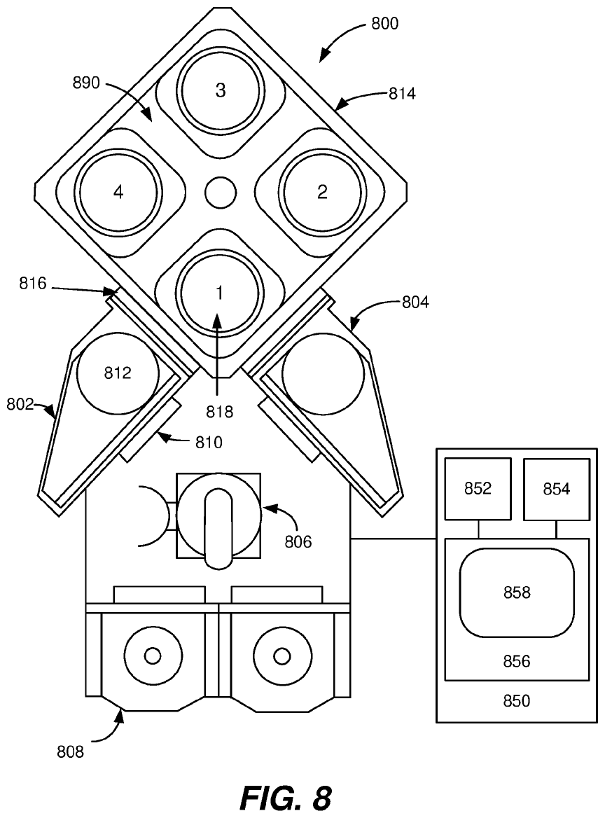

FIG. 8 shows a schematic view of an embodiment of a multi-station processing tool 800 with an inbound load lock 802 and an outbound load lock 804, either or both of which may comprise a remote plasma source. Such tool may be used for processing the substrates using the methods provided herein. A robot 806, at atmospheric pressure, is configured to move wafers from a cassette loaded through a pod 808 into inbound load lock 802 via an atmospheric port 810. A wafer is placed by the robot 806 on a pedestal 812 in the inbound load lock 802, the atmospheric port 810 is closed, and the load lock is pumped down. Where the inbound load lock 802 comprises a remote plasma source, the wafer may be exposed to a remote plasma treatment in the load lock prior to being introduced into a processing chamber 814. Further, the wafer also may be heated in the inbound load lock 802 as well, for example, to remove moisture and adsorbed gases. Next, a chamber transport port 816 to processing chamber 814 is opened, and another robot (not shown) places the wafer into the reactor on a pedestal of a first station shown in the reactor for processing. While the embodiment depicted in FIG. 8 includes load locks, it will be appreciated that, in some embodiments, direct entry of a wafer into a process station may be provided.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. While the depicted processing chamber 814 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 also depicts an embodiment of a wafer handling system 890 for transferring wafers within processing chamber 814. In some embodiments, wafer handling system 890 may transfer wafers between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc.

In some embodiments, system controller 850 controls all of the activities of process tool 800. System controller 850 executes system control software 858 stored in mass storage device 854, loaded into memory device 856, and executed on processor 852. System control software 858 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 800. System control software 858 may be configured in any suitable way. For example, various process tool component subroutines or control objects may be written to control operation of the process tool components necessary to carry out various process tool processes in accordance with the disclosed methods. System control software 858 may be coded in any suitable computer readable programming language.

In some embodiments, system control software 858 may include input/output control (IOC) sequencing instructions for controlling the various parameters described above. For example, each phase of an ALD process may include one or more instructions for execution by system controller 850. The instructions for setting process conditions for an ALD process phase may be included in a corresponding ALD recipe phase. In some embodiments, the ALD recipe phases may be sequentially arranged, so that all instructions for an ALD process phase are executed concurrently with that process phase.

Other computer software and/or programs stored on mass storage device 854 and/or memory device 856 associated with system controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 850. The user interface may include a display screen, graphical software displays of the apparatus and/or process conditions, and user input devices such as pointing devices, keyboards, touch screens, microphones, etc.

In some embodiments, parameters adjusted by system controller 850 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of process tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Two or more of the stations may perform the same functions. Similarly, two or more stations may perform different functions. Each station can be designed/configured to perform a particular function/method as desired.

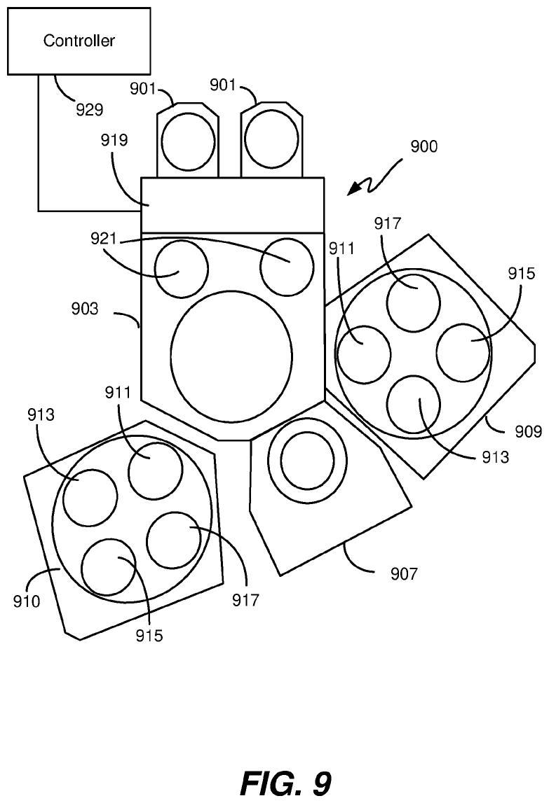

FIG. 9 is a block diagram of a processing system suitable for conducting thin film deposition processes in accordance with certain embodiments. The system 900 includes a transfer module 903. The transfer module 903 provides a clean, pressurized environment to minimize risk of contamination of substrates being processed as they are moved between various reactor modules. Mounted on the transfer module 903 are two multi-station reactors 909 and 910, each capable of performing atomic layer deposition (ALD) and/or chemical vapor deposition (CVD) according to certain embodiments. Reactors 909 and 910 may include multiple stations 911, 913, 915, and 917 that may sequentially or non-sequentially perform operations in accordance with disclosed embodiments. The stations may include a heated pedestal or substrate support, one or more gas inlets or showerhead or dispersion plate.

Also mounted on the transfer module 903 may be one or more single or multi-station modules 907 capable of performing plasma or chemical (non-plasma) pre-cleans, or any other processes described in relation to the disclosed methods. The module 907 may in some cases be used for various treatments to, for example, prepare a substrate for a deposition process. The module 907 may also be designed/configured to perform various other processes such as etching or polishing. The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all of the activities of the deposition apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 929 may be employed in some embodiments.

Typically, a user interface will be associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface. Signals for monitoring the process may be provided by analog and/or digital input connections of the system controller 929. The signals for controlling the process are output on the analog and digital output connections of the deposition apparatus 900.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer.

In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Further Implementations

The apparatus and processes described herein may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for performing bottom-up gapfill of features of a substrate comprising:
(a) providing a substrate including a plurality of features, each feature comprising a feature opening and a feature bottom, in a process chamber;
(b) introducing a metal halide precursor into the process chamber:
(c) introducing a reducing agent into the process chamber; and
(d) introducing a halogen-containing etchant into the process chamber; and
wherein (d) occurs during a duration of (c); and a duration of (d) is the same as or shorter than the duration of (c) whereby the metal halide precursor reacts with the reducing agent to deposit a metal film in the feature and the halogen-containing etchant preferentially etches the metal film near the feature opening with respect to the metal film near the feature bottom.

2. The method of claim 1, wherein the metal film comprises molybdenum or tungsten.

3. The method of claim 1, wherein the reducing agent is hydrogen.

4. The method of claim 1, wherein the halogen-containing etchant and the metal halide precursor comprise the same halogen.

5. The method of claim 1, wherein the metal halide precursor comprises a molybdenum halide precursor or a tungsten halide precursor.

6. The method of claim 1, wherein the halogen-containing etchant comprises HCl, Cl₂, MoCl₅, HBr, HF, F₂, MoF₆, or a combination thereof.

7. The method of claim 5, wherein the molybdenum halide precursor comprises a molybdenum halide, a molybdenum oxyhalide or a combination thereof.

8. The method of claim 7, wherein the molybdenum halide comprises molybdenum dichloride, molybdenum trichloride, molybdenum tetrachloride, molybdenum pentachloride, molybdenum hexachloride, molybdenum hexafluoride or molybdenum fluoride.

9. The method of claim 7, wherein the molybdenum oxyhalide comprises molybdenum dichloride dioxide, molybdenum tetrachloride oxide, molybdenum tetrafluoride oxide or molybdenum dibromide dioxide.

10. The method of claim 5, wherein the tungsten halide precursor comprises tungsten hexafluoride, tungsten pentafluoride, tungsten hexachloride, tungsten pentachloride or a combination thereof.

11. The method of claim 1, wherein a ratio of reducing agent to etchant may be from about 10:1 to about 1:10.

12. The method of claim 1, wherein a concentration of etchant is increased or decreased during (d).

13. The method of claim 1, wherein the duration of (b) is the same as the duration of (c).

14. The method of claim 1, wherein the substrate is not removed from the processing chamber during or between any of operations (a) through (d).

15. The method of claim 1, wherein the bottom-up gapfill is performed by atomic layer deposition, plasma enhanced atomic layer deposition, pulsed chemical vapor deposition or plasma enhanced chemical vapor deposition.

16. The method of claim 1, wherein a temperature of the process chamber is maintained at less than about 400° C.

17. The method of claim 16, wherein the temperature of the process chamber is maintained at about 200° C. to about 300° C., and the process chamber has a pressure of less than about 500 Torr.

18. An apparatus for filling a feature of a semiconductor substrate, the apparatus comprising:
one or more process chambers;
one or more gas inlets into the process chambers and associated flow-control hardware; and
a controller having at least one processor and a memory, wherein
the at least one processor and the memory are communicatively connected with one another,
the at least one processor is at least operatively connected with the associated flow-control hardware, and
the memory stores computer-executable instructions for controlling the at least one processor to at least control the associated flow-control hardware to:
(a) cause introduction of a metal halide precursor into the process chamber;
(b) cause introduction of a reducing agent into the process chamber; and
(c) cause introduction of a halogen-containing etchant into the process chamber; and
wherein (c) occurs during a duration of (b); and the duration of (c) is the same as or shorter than the duration of (b).

19. The apparatus of claim 18, further comprising a plasma generator for providing pulsed plasma to the one or more process chambers.

20. A method for performing bottom-up gapfill of features of a substrate comprising:
(a) providing a substrate including a plurality of features, each feature comprising a feature opening and a feature bottom, in a process chamber;
(b) introducing a metal halide precursor into the process chamber;
(c) introducing a reducing agent into the process chamber; and
(d) introducing a halogen-containing etchant into the process chamber; and
wherein (c) occurs during a duration of (d); and the duration of (c) is the same as or shorter than the duration of (d) whereby the metal halide precursor reacts with the reducing agent to deposit a metal film in the feature and the halogen-containing etchant preferentially etches the metal film near the feature opening with respect to the metal film near the feature bottom.
